(19) United States
(12) Patent Application Publication
(10) Pub. No.: US 2011/0209420 A1
(43) Pub. Date: Sep. 1, 2011

(54) Photovoltaic Elements, Systems, Methods And Kits

(76) Inventors: Walter Roach, Telford, PA (US); Robert Jenkins, Honeybrook, PA (US)

(21) Appl. No.: 12/984,438

(22) Filed: Jan. 4, 2011

Related U.S. Application Data
(60) Provisional application No. 61/291,954, filed on Jan. 4, 2010.

(51) Int. Cl. E04D 13/18; H01L 31/048; B23P 11/00

(52) U.S. Cl. 52/173.3; 136/251; 29/428

(57) ABSTRACT

The present invention relates generally to the photovoltaic generation of electrical energy. The present invention relates more particularly to photovoltaic products for use in photovoltaically generating electrical energy. One aspect of the invention is a photovoltaic element comprising: a top face and a plurality of lateral sides; one or more photovoltaic cells defining a photovoltaic region on the top face, the photovoltaic region extending substantially to one or more of the lateral sides; and one or more selvage edges disposed along one or more of the lateral sides to which the photovoltaic region does not extend.

### SUMMARY OF THE INVENTION

The present application claims priority to U.S. Provisional Patent Application Ser. No. 61/291,954, which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic products for use in photovoltaically generating electrical energy.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as system performance has improved. They can be used to provide at least a significant fraction of the electrical energy needed for a building's overall function; or they can be used to power one or more particular devices, such as exterior lighting systems and well pumps.

Accordingly, research and development attention has turned toward the development of photovoltaic products that are adapted to be installed on a roof. While photovoltaic modules have been in use for some time, they tend to be heavy and bulky, and aesthetically unfavorable when installed on a roof. Roofing products having photovoltaic cells integrated with roofing products such as shingles, shakes or tiles have been proposed. A plurality of such photovoltaic roofing elements (i.e., including photovoltaic media integrated with a roofing product) can be installed together on a roof, and electrically interconnected to form a photovoltaic roofing system that provides both environmental protection and photovoltaic power generation. These can be very advantageous, but can be difficult to install on steep surfaces, and can often result in incomplete coverage of the roof surface with photovoltaic power generation.

### SUMMARY OF THE INVENTION

One aspect of the invention is a photovoltaic element comprising
a top face and a plurality of lateral sides;
one or more photovoltaic cells defining a photovoltaic region on the top face, the photovoltaic region extending substantially to one or more of the lateral sides; and
one or more selvage edges disposed along one or more of the lateral sides to which the photovoltaic region does not extend.

Another aspect of the invention is a photovoltaic system including a plurality of photovoltaic elements as described above, electrically interconnected. The photovoltaic system can be, for example, disposed on a roof

Another aspect of the invention is a kit for the assembly of a photovoltaic system, the kit including a plurality of photovoltaic elements as described above.

The photovoltaic elements, systems and kits of the present invention can result in a number of advantages. In certain embodiments, the selvage edges can provide a place for mechanical attachment, which can be especially useful on highly sloped surfaces. In certain embodiments, the selvage edges can be used to provide environmental protection to the underlying surface, so that other structures (e.g., shingles) are not necessary. Other advantages will be apparent to the person of skill in the art.

### BRIEF DESCRIPTION OF THE DRAWINGS

The accompanying drawings are not necessarily to scale, and sizes of various elements can be distorted for clarity.

FIG. 1 is a schematic top view, and FIG. 2 is a schematic cross-sectional view of a photovoltaic element according to one embodiment of the invention;

FIG. 3 is a partial schematic cross-sectional view of two overlapping photovoltaic elements according to one embodiment of the invention;

FIG. 4 is a partial schematic cross-sectional view of two overlapping photovoltaic elements according to another embodiment of the invention;

FIG. 5 is a top schematic view of a photovoltaic element according to one embodiment of the invention;

FIG. 6 is a top schematic view of a photovoltaic element according to another embodiment of the invention;

FIG. 7 is a top schematic view of a photovoltaic element according to yet another embodiment of the invention;

FIG. 8 is a top schematic view of the photovoltaic element of FIG. 7 as installed, shown together with surrounding photovoltaic elements in dotted line;

FIG. 9 is a top schematic view of a hexagonal photovoltaic element as installed, shown together with surrounding photovoltaic elements in dotted line;

FIG. 10 is a partial schematic cross-sectional view of a photovoltaic element according to one embodiment of the invention;

FIG. 11 is a partial schematic cross-sectional view of a photovoltaic element according to another embodiment of the invention;

FIG. 12 is a schematic cross-sectional/perspective view of a photovoltaic element having a raised feature according to one embodiment of the invention;

FIG. 13 is a schematic exploded perspective view of a photovoltaic element according to various aspects of the invention;

FIG. 14 is a picture of electrical connectors suitable for use in practicing the present invention; and

FIG. 15 is a top schematic view, and FIG. 16 is a cross-sectional schematic view of a photovoltaic system comprising an array of photovoltaic elements according to one embodiment of the invention.

### DETAILED DESCRIPTION OF THE INVENTION

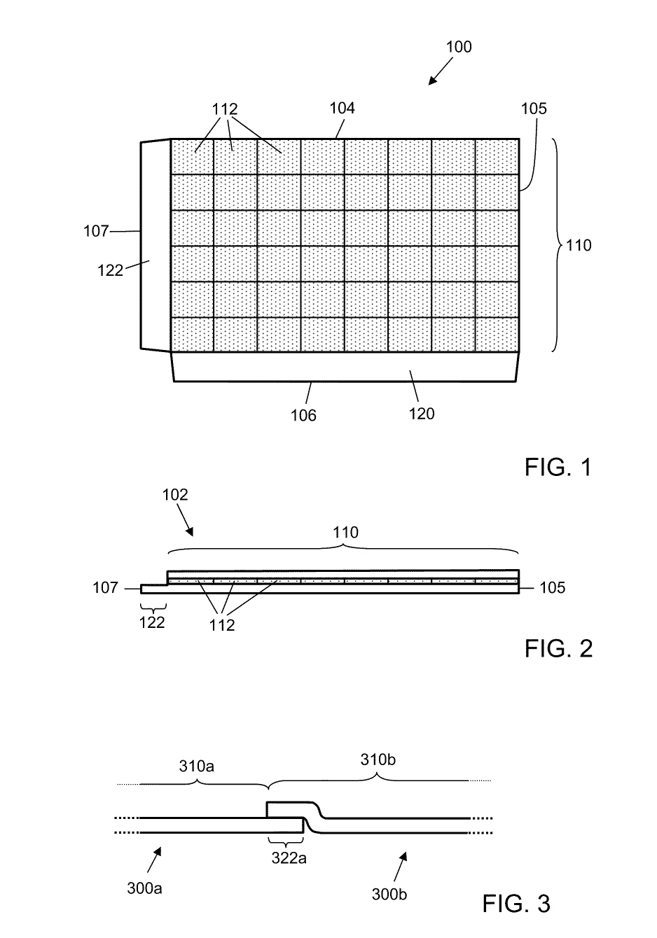

One aspect of the invention provides a photovoltaic element comprising a top face and a plurality of lateral sides; one or more photovoltaic cells defining a photovoltaic region on the top face, the photovoltaic region extending substantially to one or more of the lateral sides; and one or more selvage edges disposed along one or more of the lateral sides to which the photovoltaic region does not substantially extend. FIG. 1 is a schematic top view, and FIG. 2 is a schematic cross-sectional view of a photovoltaic element according to one embodiment of the invention. Photovoltaic element 100 has a top face 102, and a plurality of lateral sides 104, 105, 106, 107 includes a plurality of photovoltaic cells 112, which define photovoltaic region 110. The photovoltaic region 110 extends substantially to lateral sides 104 and 105 of the photovoltaic element. In this embodiment, the photovoltaic region extends all the way out to lateral side 104 and 105. In other embodiments, the photovoltaic region can extend to, for example, within 5 mm of one or more of the lateral sides of the photovoltaic element. The photovoltaic element 100 also includes two selvage edges 120 and 122, which are disposed along lateral sides 106 and 107, respectively. Notably, the photovoltaic region 110 does not substantially extend to lateral sides 106 and 107. For example, in certain embodiments, the photovoltaic region does not extend to within 1 cm, or even within 2 cm of the lateral sides.

In use, and as described in more detail herein, the selvage edges can be disposed underneath adjacent photovoltaic elements, providing continuous coverage of the surface on which they are disposed. The selvage edge can in some embodiments be adhered to the overlying photovoltaic element, providing a watertight seal. The selvage edge can also provide an area for mechanical fastening, especially on steep, non-walkable surfaces upon which slippage due to heat and gravity can be an issue. In certain aspects of the invention, the selvage edge is not photovoltaically-active.

In certain embodiments of the invention as described herein, for example, as shown in FIG. 2, the selvage edges are substantially thinner than the photovoltaic element in the photovoltaic region. In such embodiments, the selvage edges can more easily fit underneath adjacent photovoltaic elements. For example, in certain elements, the selvage edges have thicknesses of less than about 2 mm, or even less than about 1 mm. Relatively thin selvage edges can be especially useful when the photovoltaic element is relatively rigid.

In other embodiments of the invention as described herein, the selvage edges are not substantially thinner than the photovoltaic element in the photovoltaic region. Such embodiments can be useful, for example, when the photovoltaic element is relatively flexible. For example, some photovoltaic elements are formed as thin, relatively flexible laminate structures. In such embodiments, the photovoltaic element can flex to overlap a selvage edge that is about as thick as the photovoltaic element in the photovoltaic region. For example, as shown in partial schematic cross-sectional view in FIG. 3, the selvage edge 322a of photovoltaic element 300a (but not its photovoltaic region 310a) is overlapped by the photovoltaic region 310b of photovoltaic element 300b. While the selvage edge 322a of photovoltaic element 300a is about as thick as the photovoltaic elements 300a and 300b in their photovoltaic regions, photovoltaic element 300b is flexible enough to bend over the top of the selvage edge, then down onto the underlying surface.

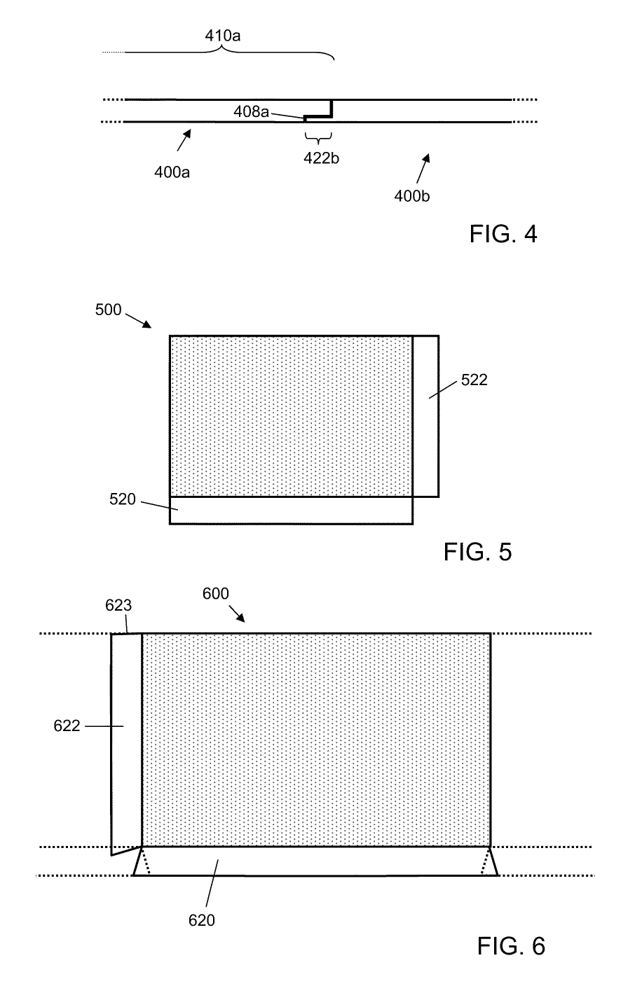

In certain embodiments of the invention as described herein, the photovoltaic element can have a recess formed in its bottom surface along the side opposite a selvage edge, so that the selvage edge of an adjacent photovoltaic element can fit therein. For example, as shown in partial schematic cross-sectional view in FIG. 4, the selvage edge 422b of photovoltaic element 400b is overlapped by the photovoltaic region 410a of photovoltaic element 400a. Photovoltaic element 400a has a recess 408a formed in its bottom surface along a side opposite a selvage edge (not shown), so that the selvage edge 422b of photovoltaic element 400b can fit therein. Use of a recess can allow the overlapping photovoltaic element to remain relatively undistorted.

In certain embodiments of the invention as described herein, for example as shown in FIG. 1, the selvage edges are contiguous with the photovoltaic region. In certain such embodiments, the photovoltaic region can include substantially the entire top surface of the photovoltaic element, such that, when the selvage edges are disposed underneath adjacent photovoltaic elements, substantially the entire exposed top surface of the photovoltaic element can have the capacity for photovoltaic power generation. In this way, a surface (e.g., a roof surface) can very space-efficiently be outfitted with photovoltaic power generating capabilities. Moreover, in the embodiments shown in FIGS. 3 and 4, the photovoltaic regions of adjacent photovoltaic elements can substantially contiguous when installed, which can allow for efficient coverage of a surface (e.g., a roof surface) with photovoltaic power generating capability.

The selvage edges can have a variety of shapes. For example, they can extend from the photovoltaic area, as shown in FIG. 1. The selvage edges can in some embodiments be trapezoidal with at least one side slanted in toward the center of the selvage edge, as shown in FIG. 1, or rectangular, as shown by selvage edges 520 and 522 of the photovoltaic element 500 of FIG. 5.

In certain embodiments, at least one selvage edge is trapezoidal in shape with at least one side slanted away from the center of the selvage edge, as shown in schematic top view in FIG. 6. In photovoltaic element 600 of FIG. 6, both sides of trapezoidal selvage edge 620 slant away from its center. In such embodiments, the selvage edges of two laterally adjacent photovoltaic elements can overlap (as shown by the dotted line in FIG. 6). However, in certain embodiments, the side of the selvage edge that is to be disposed along a previously-installed course of photovoltaic elements is not slanted away from the center of the selvage edge. As shown in FIG. 6, side 623 of trapezoidal selvage edge 622 is not slanted away from the center of the selvage edge. Accordingly, this selvage edge will not cover the photovoltaic region of the photovoltaic element of a previously installed course.

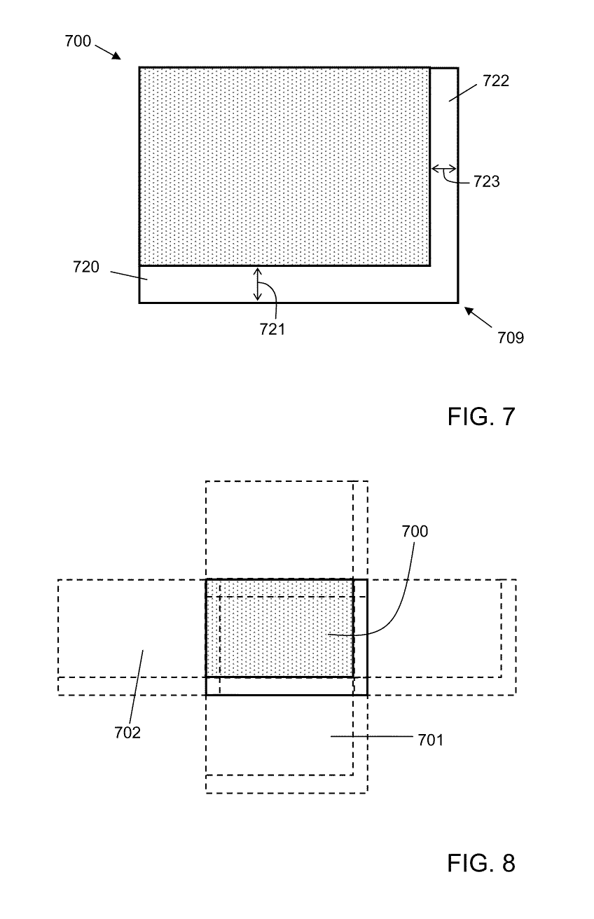

In certain embodiments, selvage edges on adjacent sides of the photovoltaic element are contiguous to one another. In photovoltaic element 700 of FIG. 7, selvage edges 720 and 722 are contiguous to one another at the corner 709 of the photovoltaic element. The selvage edges of adjacent photovoltaic elements 700, 701 and 702 can overlap one another, as shown in FIG. 8, providing additional water-resistance.

In certain embodiments, the one or more selvage edges have lateral dimensions of no more than 8″. For example, as shown in FIG. 7, selvage edge 720 has a lateral dimension 721, and selvage edge 722 has a lateral dimension 723. In certain embodiments, the lateral dimension of the selvage edge is at least about 1″, at least about 2″, or even at least about 3″. The lateral dimensions can be, for example, in the range of about 2″ to about 7″. In certain embodiments, for example, a selvage edge that is to be overlapped by a horizontally-adjacent photovoltaic element on a sloped or vertical surface can be about 4″ in lateral dimension; and a selvage edge that is to be overlapped by a vertically-adjacent photovoltaic element on a sloped or vertical surface can be about 6″ in lateral dimension. In certain embodiments, the selvage edges have a lateral dimension that is less than two times the corresponding lateral dimension of the photovoltaic region (i.e., the dimension of the photovoltaic region along the same axis as the lateral dimension of the selvage edge). For example, the selvage edge can have a lateral dimension less than the corresponding lateral dimension of the photovoltaic region. Of course, in other embodiments the selvage edges can have different lateral dimensions. The person of skill in the art can select lateral dimensions for the selvage edges that will provide a sufficient level of overlap for a desired level of environmental protection.

In certain embodiments, the photovoltaic element has at least two selvage edges. The selvage edges can be, for example, at least about 1″, at least about 2″, or even at least about 3″ in lateral dimension. The at least two selvage edges are desirably disposed on non-parallel sides of the photovoltaic element.

The photovoltaic elements of the present invention can have a variety of shapes. For example, in one embodiment, the photovoltaic element has a parallelogram shape, with two selvage edges disposed along adjacent size of the parallelogram. The photovoltaic elements of FIGS. 1-8 are shown as being rectangular. In other embodiments, the shape of the photovoltaic element is a non-rectangular quadrilateral (e.g., a rhomboid).

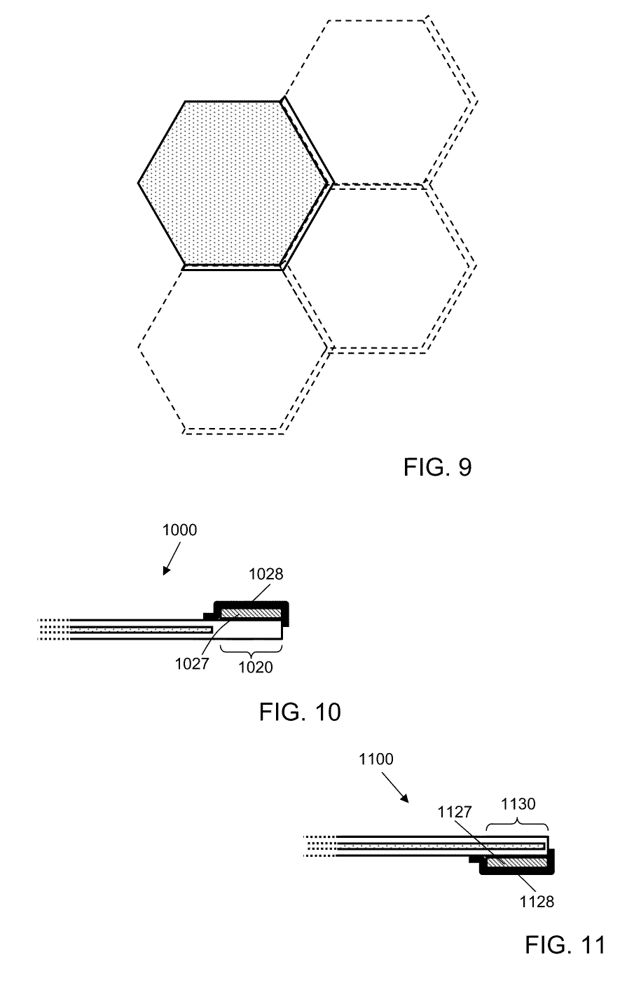

In other embodiments, the photovoltaic element has a regular hexagonal shape, with three selvage edges. The selvage edges are not disposed along parallel sides of the regular hexagon. An example of such a photovoltaic element is shown in top schematic view in FIG. 9 (with overlapping photovoltaic elements in dashed line).

In certain embodiments, the one or more selvage edges have adhesive materials disposed on their top surfaces. The adhesive material can be used to adhere the top surface of the selvage edge to the bottom surface of an overlying photovoltaic element, thereby making a seal and protecting from the elements the surface upon which the photovoltaic elements are disposed. The adhesive material can have disposed upon it a releasable liner (e.g., paper, polymer, foil), that can cover adhesive material during shipment and assembly on the roof, then removed to expose the adhesive for adherence to an overlying photovoltaic element. For example, as shown in partial schematic cross-sectional view in FIG. 10, the selvage edge 1020 of photovoltaic element 1000 has an adhesive material 1027 disposed thereon. The adhesive material 1027 is covered by a releasable liner 1028, which can be peeled off to expose the adhesive material. The releasable liner can be, for example, release-coated paper. The adhesive material can be, for example, a pressure sensitive adhesive such as a functionalized EVA-based pressure-sensitive adhesive (e.g., HB Fuller 9917).

In certain embodiments, the photovoltaic element has an adhesive material disposed on its bottom surface along its edges opposing the one or more selvage edges. The adhesive material can be used to adhere the bottom surface of the photovoltaic element to the selvage edge of an underlying photovoltaic element, thereby making a seal and protecting from the elements the surface upon which the photovoltaic elements are disposed. The adhesive material can have disposed upon it a removable cover (e.g., paper, polymer, foil), that can cover adhesive material during shipment and assembly on the roof, then removed to expose the adhesive for adherence to the selvage edge of an underlying photovoltaic element. For example, as shown in partial schematic cross-sectional view in FIG. 11, the bottom surface of the edge 1130 of photovoltaic element 1100 has an adhesive material 1127 disposed thereon. The adhesive material 1127 is covered by a releasable liner 1128, which can be peeled off to expose the adhesive material. The releasable liner can be, for example, release-coated paper. The adhesive material can be, for example, a pressure sensitive adhesive such as a functionalized EVA-based pressure-sensitive adhesive (e.g., HB Fuller 9917).

In certain embodiments using adhesives as described above, the surface to which the adhesive is to adhere (e.g., the bottom surface of the edge of an adjacent photovoltaic element in the embodiment described with respect to FIG. 10, or the selvage edge of an adjacent photovoltaic element in the embodiment described with respect to FIG. 11) is adapted to be receptive to the adhesive.

For example, in one embodiment of the invention, the surface to which the adhesive is to adhere is textured. The surface can include, for example, a textured layer such as a fabric, scrim, a woven or non-woven web, a felt, a porous film, or a sheet having a microstructured surface. In other embodiments, the surfacing includes a texturing material such as sand, glass or quartz grit, fibers (e.g., polymeric, glass). The textured layer can provide additional surface area for adhesion. In certain embodiments of the invention, the material of the textured layer is at least partially embedded in the material of the surface to be adhered. For example, in one embodiment, the surfacing includes a textured web (e.g., fiberglass mat) coated on one side (e.g., with a polymeric coating), with its uncoated side embedded in the material of the top surface of the photovoltaic element. In this embodiment, the coating can provide increased adhesion to the adhesive, while the embedded textured web improves adhesion to the photovoltaic element. In other embodiments of the invention, the textured surfacing is achieved by mechanically embossing or chemically etching the surface.

In other embodiments of the invention, the surface to be adhered includes a polymer material or a metal foil. The polymer material or metal foil can provide enhanced adhesion. For example, the surfacing can be a polymer film formed from a polymer such as a fluorinated polymer, an acrylic polymer, a urethane polymer, a polyester, or a polyolefin. In other embodiments, the surfacing of the one or more receptor zones includes a metal foil, such as an aluminum foil or a steel foil. For example, in one embodiment, 2 mil thickness deadsoft aluminum foil available from Kaiser aluminum is laminated to portions of the surface to be adhered. The polymer film or metal foil can be surface-treated (e.g., as described below) to enhance adhesion.

In some embodiments of this invention, the surface to be adhered can be surface treated to enhance its affinity for the adhesive. Examples of the surface treatments include flame treatment, plasma treatment, corona treatment, ozone treatment, sodium treatment, etching, ion implantation, electron beam treatment, or combinations thereof. Surface treatments can also include chemical modification with reactive organic species such as polymerizable monomers, or coupling agents such as organosilanes, organozirconates or organotitanates.

In certain embodiments, adhesive materials are disposed on the top surfaces of the selvage edges, as described above with respect to FIG. 10, and on the bottom surface along its edges opposing the one or more selvage edges, as described above with FIG. 11. In these embodiments, the adhesives can come together to form a bond.

In certain embodiments, the selvage edge has a relatively rigid material disposed thereon. The rigid material can be relatively thin, and can be, for example, metal, plastic or composite. The rigid material can act to provide additional structural integrity to the selvage edge, or, if larger in lateral dimension than the selvage edge, can provide additional environmental resistance when lapped under an adjacent photovoltaic element. The relatively rigid material can be relatively thin, for example less than 2 mm, or even less than 1 mm in thickness. The relatively rigid material can be, for example, substantially more rigid than the material of the selvage edge. The relatively rigid material can be disposed between the selvage edge and a layer of adhesive material.

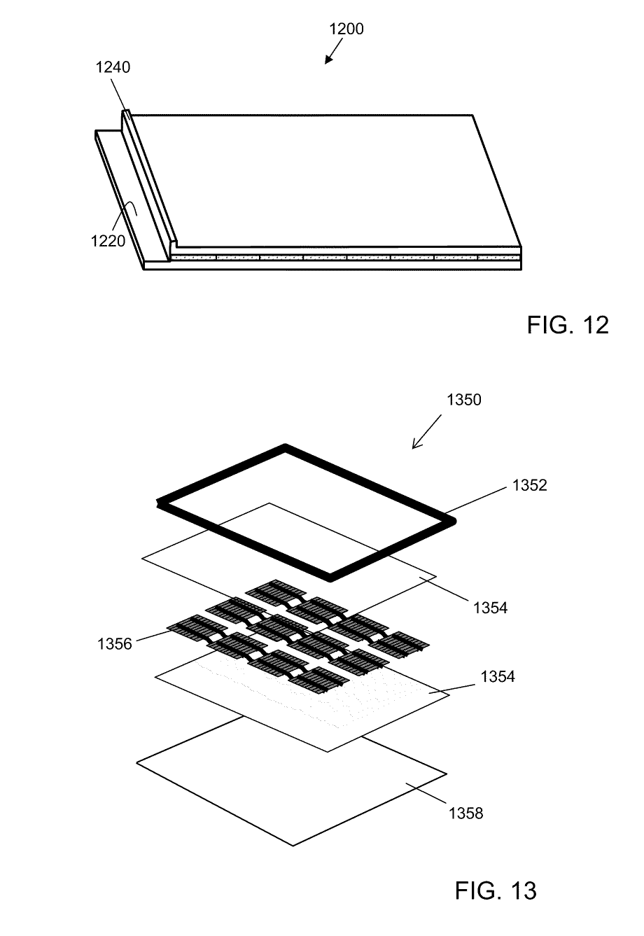

In certain embodiments of the invention as described herein, the photovoltaic element includes a raised feature on its top surface adjacent one or more of the selvage edges. The raised feature, can, for example, be formed continuously along the selvage edge. A raised feature can provide a dimensional appearance to an installed array of photovoltaic elements, and can also be used as a laying line for placement of an overlapping photovoltaic element. The raised feature can vary in height and width, depending on the desired dimensional appearance. An example of a photovoltaic element with a raised feature is shown in schematic cross-sectional/perspective view in FIG. 12. Photovoltaic element 1200 includes selvage edge 1220, and raised feature 1240.

The photovoltaic elements of the present invention can be formed in a variety of ways. In one embodiment, the photovoltaic element is formed as a laminate or encapsulate structure, and the selvage edge is formed from a layer of the laminate or encapsulate material.

For example, an exploded view of a photovoltaic laminate element according to one embodiment of the invention is provided as FIG. 13. The photovoltaic elements can be encapsulated photovoltaic elements, in which photovoltaic cells are encapsulated between various layers of material (e.g., as a laminate). For example, a photovoltaic laminate can include a top laminate layer at its top surface, and a bottom laminate layer at its bottom surface. The top laminate layer material can, for example, provide environmental protection to the underlying photovoltaic cells, and any other underlying layers. Examples of suitable materials for the top layer material include fluoropolymers, for example ETFE (“TEFZEL”, or NORTON ETFE), PFE, FEP, PVF (“TEDLAR”), PCTFE or PVDF. The top laminate layer material can alternatively be, for example, a glass sheet, or a non-fluorinated polymeric material (e.g., polypropylene). The bottom laminate layer material can be, for example, a fluoropolymer, for example ETFE (“TEFZEL”, or NORTON ETFE), PFE, FEP, PVDF or PVF (“TEDLAR”). The bottom laminate layer material can alternatively be, for example, a polymeric material (e.g., polyolefin such as polypropylene, polyester such as PET); or a metallic material (e.g., steel or aluminum sheet).

As the person of skill in the art will appreciate, a photovoltaic laminate can include other layers interspersed between the top laminate layer and the bottom laminate layer. For example, a photovoltaic laminate can include structural elements (e.g., a reinforcing layer of glass, metal, glass or polymer fibers, a rigid film, or a flexible film); adhesive layers (e.g., EVA to adhere other layers together); mounting structures (e.g., clips, holes, or tabs); one or more electrical components (e.g., electrodes, electrical connectors; optionally connectorized electrical wires or cables) for electrically interconnecting the photovoltaic cell(s) of the encapsulated photovoltaic element with an electrical system. As described in more detail below, the return electrical path, any series interconnections between photovoltaic elements, and any bypass diodes can be included within the laminate. An example of a photovoltaic laminate suitable for use in the present invention is shown in schematic exploded view FIG. 13. Encapsulated photovoltaic element 1350 includes a top protective layer 1352 (e.g., glass or a fluoropolymer film such as ETFE, PVDF, PVF, FEP, PFA or PCTFE); encapsulant layers 1354 (e.g., EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells 1356 (which can include the return electrical path and bypass diode as described above); and a backing layer 1358 (e.g., PVDF, PVF, PET).

Notably, the selvage edge can be formed from a layer of the laminate or encapsulant material. In the exploded view of FIG. 13, the backing layer 1358 is wider than the other layers, so that, when put together, the edge of the backing layer can form the selvage edge. Of course, in other embodiments, the selvage edge can be formed by molding, or by building the photovoltaic element on a substrate that is larger than the one or more photovoltaic cells. The substrate can be, for example, a roofing substrate, for example a flexible roofing substrate as described below. In certain embodiments, the selvage edge can be formed as a separate piece, then attached (e.g., mechanically or adhesively) to the rest of the photovoltaic element.

The present invention can be practiced using any of a number of types of roofing substrates. For example, a flexible roofing substrate can be an asphalt shingle, a bituminous shingle or a plastic shingle. For example, the flexible roofing substrate can be a multilayer asphalt shingle. The manufacture of photovoltaic elements using a variety of roofing substrates are described, for example, in U.S. Patent Application Publications nos. 2009/0000222, 20090133340, 2009/0133740, 2009/0178350, 2009/0159118 and 2007/0266562, each of which is hereby incorporated herein by reference in its entirety. Asphalt shingle constructions are known in the shingle art and can be used as the flexible roofing substrates in various aspects of the present invention. Alternatively, other flexible base materials such as elastomeric membrane, polyvinylchloride membrane, thermoplastic polyolefin membrane or other flexible polymeric materials may be used. In certain embodiments, the photovoltaic element can be built on a roofing membrane, with the material of the membrane forming the selvage edges. Rigid substrates can also be used.

Photovoltaic elements according to various aspects of the present invention can include one or more interconnected photovoltaic cells provided together in a single package. The photovoltaic cells of the photovoltaic elements can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide and copper indium gallium selenide. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of photovoltaic elements for use in the present invention. In one embodiment of the invention, the photovoltaic element includes a monocrystalline silicon photovoltaic cell or a polycrystalline silicon photovoltaic cell. The photovoltaic elements according to various aspects of the present invention can be flexible, or alternatively can be rigid.

The photovoltaic element can include at least one antireflection coating, for example as the top layer material in an encapsulated photovoltaic element, or disposed between the top layer material and the photovoltaic cells. The photovoltaic element can also be made colored, textured, or patterned, for example by using colored, textured or patterned layers in the construction of the photovoltaic element. Methods for adjusting the appearance of photovoltaic elements are described, for example, in U.S. Provisional Patent Application Ser. No. 61/019,740, and U.S. Patent Application Publications nos. 2008/0006323, 2008/0271773, 2009/0000221, 2009/0133738 and 2009/0133739 each of which is hereby incorporated herein by reference in its entirety.

Photovoltaic elements can be obtained, for example, from China Electric Equipment Group of Nanjing, China, as well as from several domestic suppliers such as Uni-Solar Ovonic, Sharp, Shell Solar, BP Solar, USFC, FirstSolar, Ascent Solar, General Electric, Schott Solar, Evergreen Solar and Global Solar. As described above, a selvage edge can be provided as a separate piece and affixed to these commercially-available photovoltaic elements. Flexible photovoltaic elements are commercially available from Uni-Solar as L-cells having a dimension of approximately 9.5″×14″, S-cells having dimensions of approximately 4.75″×14″, and T-cells having dimensions of approximately 4.75″×7″. Moreover, the person of skill in the art can fabricate photovoltaic laminates using techniques such as lamination or autoclave processes. Photovoltaic laminates can be made, for example, using methods disclosed in U.S. Pat. No. 5,273,608, which is hereby incorporated herein by reference in its entirely.

The photovoltaic element also has an operating wavelength range. Solar radiation includes light of wavelengths spanning the near UV, the visible, and the near infrared spectra. As used herein, the term “solar radiation,” when used without further elaboration means radiation in the wavelength range of 300 nm to 2500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the photovoltaic element falls within the range of about 300 nm to about 1200 nm.

The photovoltaic element can also include a bypass diode. The person of skill in the art will select bypass diode characteristics depending on a number of factors. The characteristics of the diode will depend, for example, on the type and size of photovoltaic element used, the intensity and variability of sunlight expected at the installation location, and the resistance at which a shaded photovoltaic element causes unacceptable system inefficiency. For example, the bypass diode can be configured to bypass a photovoltaic element when its output drops below about 30% of its maximum (i.e., in full sunlight at noon on the solstice) output (i.e., a about 30% or greater degradation in photovoltaically-generated current), below about 50% of its maximum output, below about 70% of its maximum output, below about 90% of its maximum output, or even below about 95% of its maximum output. For example, in one embodiment, in a 20 cell series-connected array of 1 volt/5 amp producing photovoltaic elements, the bypass diodes can be selected to bypass the photovoltaic elements when the output current drops below 4.75 amps (i.e., below 95% of the maximum output). Of course, as the person of skill will appreciate, each system design will have its own set of parameters; with higher amperage systems, relatively more degradation of current can be tolerated. In certain embodiments, the bypass diode can be an 8 amp bypass diode, available from Northern Arizona Wind & Sun, Flagstaff, Ariz.

In other embodiments, the bypass diode can be configured to bypass a photovoltaic element when its resistivity increases by at least about 400% of its resistivity at maximum output, at least about 300% of its resistivity at maximum output, at least about 100% of its resistivity at maximum output, at least about 50% of its resistivity at maximum output, at least about 25% of its resistivity at its maximum output, or even at least about 5% of its resistivity at maximum output.

The photovoltaic element can also include one or more electrical connectors. A variety of electrical connectors can be used in practicing the various embodiments of the invention. An electrical connector can take the form of, for example, a mating electrical connector (i.e., adapted to mate with another mating electrical connector to make an electrical connection therebetween). Mating connectors can mate with one another, for example, in a male/female fashion. An electrical connector can also take the form of a cable that interconnects a mating connector with the photovoltaic element. An electrical connector can also take a form of a junction box that interconnects various electrical wires and cables associated with the photovoltaic elements, mating connectors or other electrical components such as bypass diodes.

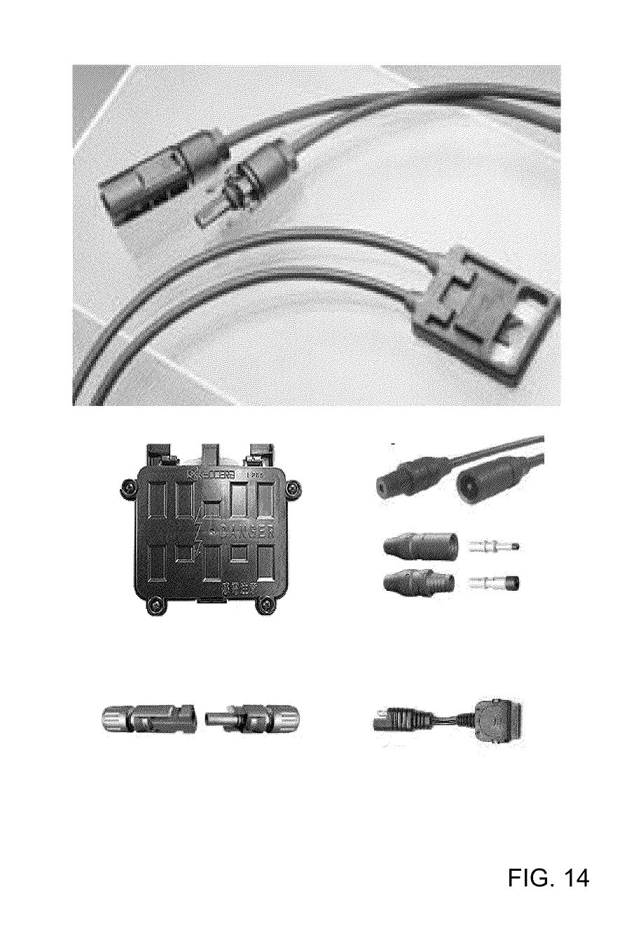

Examples of suitable electrical connectors are shown in FIG. 14. The mating connectors and junction boxes depicted are available from Tyco Electronics, Berwyn, Pa. (trade name SOLARLOK) and Multi-Contact USA of Santa Rosa, Calif. (trade name SOLARLINE). U.S. Pat. Nos. 7,445,508 and 7,387,537, U.S. Patent Application Publications nos. 2009/0318004, 2009/0194143, 2009/0133740, 2009/0126782, 2008/0271774; and U.S. patent application Ser. No. 12/634,403, each of which is hereby incorporated herein by reference in its entirety, disclose electrical connectors for use with photovoltaic products. Electrical connectors desirably meet UNDERWRITERS LABORATORIES and NATIONAL ELECTRICAL CODE standards.

Another aspect of the invention is a photovoltaic system comprising a plurality of photovoltaic elements as described herein arrayed on a surface (e.g., a roof deck). The surface can have, for example, an angle to the vertical in the range of 0° to 45°. The photovoltaic elements can be electrically interconnected, and can be interconnected with an inverter to allow photovoltaically-generated electrical power to be used on-site, stored in a battery, or introduced to an electrical grid. Any cabling interconnecting the photovoltaic elements of the invention in a photovoltaic system can, for example, be long and flexible enough to account for natural movement of the surface, for example due to heat, moisture and/or natural expansion/contraction. It will be understood that power generated by the photovoltaic systems described herein may be used to power a building upon which the surface is disposed or may be directed elsewhere on an electrical grid, as desired. Electrical systems for handling the photovoltaically-generated power are described, for example, in U.S. Patent Application Publication no. 2008/0271774, which is hereby incorporated herein by reference in its entirety.

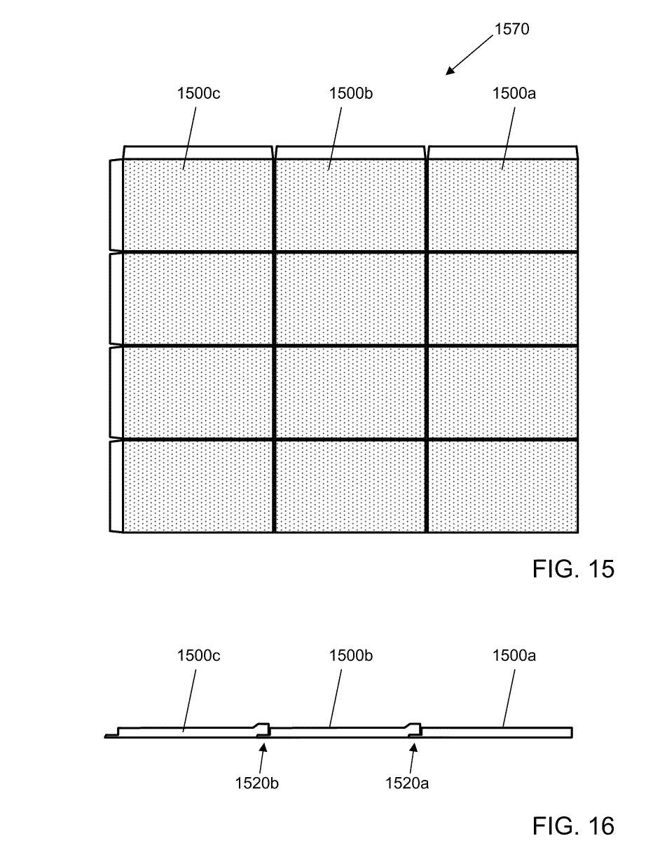

FIG. 15 is a top schematic view, and FIG. 16 is a cross-sectional schematic view of a photovoltaic system comprising an array of photovoltaic elements as described herein. Here, the photovoltaic elements are disposed as four courses of three photovoltaic elements each. Of course, in other embodiments more or less photovoltaic elements can be used; the number and configuration will depend, inter alia, on the sizes of the photovoltaic elements and the surface area to be covered. Moreover, it may be desirable to use the photovoltaic elements described with respect to FIG. 7 in a photovoltaic system, as the contiguous selvage edges can provide a higher degree of water-tightness.

In the photovoltaic system 1570, one or more of the selvage edges are covered by an edge of the adjacent photovoltaic element. For example, selvage edge 1520a of photovoltaic element 1500a is covered by an edge of adjacent photovoltaic element 1500b, and selvage edge 1520b is covered by an edge of adjacent photovoltaic element 1500c. In certain embodiments, the one or more selvage edges are adhered to the bottom surface of the edge of the adjacent photovoltaic element, as described above. An adhesive that is provided as part of the photovoltaic element (e.g., disposed on the selvage edge or on the bottom surface of an edge opposite a selvage edge, as described above) can be used as the adherent. In other embodiments, a separate adhesive material (e.g., applied during installation) can be used.

In certain embodiments, a relatively rigid material is disposed on one or more of the selvage edges, and the relatively rigid material is lapped under an adjacent photovoltaic element, as described above. The relatively rigid material can be provided as part of the photovoltaic element (e.g., disposed on the selvage edge). In other embodiments, a separate rigid material (e.g., arranged and applied during installation) can be used. The rigid material can, for example, be adhered to the selvage edge, the overlying photovoltaic element, or both.

The photovoltaic elements of the photovoltaic system of FIG. 15 are disposed in a grid fashion as sequential courses applied on a surface (surface not shown). Of course, in other embodiments, the photovoltaic elements can be disposed in other configurations, for example as laterally-offset courses.

Another aspect of the invention is a roof comprising a roof deck and a photovoltaic system as described herein disposed on the roof deck. The photovoltaic systems described herein can be utilized with many different building structures, including residential, commercial and industrial building structures. There can be one or more layers of material (e.g. underlayment), between the roof deck and the photovoltaic elements. For example, in some embodiments, the roof includes a layer of standard roofing materials between the roof deck and the photovoltaic system. However, in certain embodiments, because the overlapping photovoltaic elements can provide environmental protection, the roof need not have any standard roofing materials between the roof deck and the photovoltaic system. The roof can also include one or more standard roofing elements, for example to provide weather protection at the edges of the roof, or in areas not suitable for photovoltaic power generation. In some embodiments, non-photovoltaically-active roofing elements are complementary in appearance or visual aesthetic to the photovoltaic elements.

Another aspect of the invention is a method for installing a photovoltaic system comprising disposing a plurality of photovoltaic elements as described herein on a surface. The method can also include electrically interconnecting the photovoltaic elements, as well as interconnecting the photovoltaic elements with an inverter as described above. The disposal on the surface and electrical interconnections can be performed in any desirable order. The methods can be used to assemble a photovoltaic system as described herein.

For example, in one embodiment, the method comprises mechanically affixing each photovoltaic element to the surface through one or more of its selvage edges. The selvage edges can provide an adequate surface for nailing, screwing or stapling the photovoltaic elements to the surface.

In certain embodiments, the method includes covering one or more of the selvage edges by an edge of an adjacent photovoltaic element, as described hereinabove. Similarly, in certain embodiments, the method further includes adhering the one or more of the selvage edges to the bottom surface of the edge of the adjacent photovoltaic element, as described herein.

Another aspect of the invention is a kit for the installation of a photovoltaic system, the kit comprising a plurality of photovoltaic elements as described herein. In certain embodiments, the kit can also include an adhesive, for use in adhering adjacent photovoltaic elements as described herein above. In certain embodiments, the kit can also include rigid materials (e.g., as strips), which can be used as described hereinabove. In certain embodiments, the kit can include one or more mechanical fasteners (e.g., staples, nails, screws) for mechanically attaching the photovoltaic elements to the surface through their selvage edges, as described herein.

Further, the foregoing description of embodiments of the present invention has been presented for the purposes of illustration and description. It is not intended to be exhaustive or to limit the invention to the precise forms disclosed. As the person of skill in the art will recognize, many modifications and variations are possible in light of the above teaching. It will be apparent to those skilled in the art that various modifications and variations can be made to the present invention without departing from the scope of the invention. Thus, it is intended that the present invention cover the modifications and variations of this invention provided they come within the scope of the claims and their equivalents.

What is claimed is:

1. A photovoltaic element comprising
a top face and a plurality of lateral sides;
one or more photovoltaic cells defining a photovoltaic region on the top face, the photovoltaic region extending substantially to one or more of the lateral sides; and
one or more selvage edges disposed along one or more of the lateral sides to which the photovoltaic region does not substantially extend.

2. The photovoltaic element of claim 1, wherein the one or more selvage edges are contiguous with the photovoltaic region.

3. The photovoltaic element of claim 1, wherein the one or more selvage edges are substantially thinner than the photovoltaic element in the photovoltaic region.

4. The photovoltaic element of claim 3, wherein the one or more selvage edges have a thickness of less than about 2 mm.

5. The photovoltaic element of claim 1, wherein the one or more selvage edges extend from the photovoltaic area.

6. The photovoltaic element of claim 1, wherein selvage edges on adjacent sides of the photovoltaic element are contiguous to one another.

7. The photovoltaic element of claim 1, wherein the photovoltaic element has two or more selvage edges.

8. The photovoltaic element of claim 1, wherein the lateral dimension of each selvage edge is no more than 8″.

9. The photovoltaic element of claim 1, wherein the lateral dimension of each selvage edge is at least 1″.

10. The photovoltaic element of claim 1, lateral dimension of each selvage edge is in the range of about 2″ to about 7″.

11. The photovoltaic element of claim 1, wherein the photovoltaic element has a parallelogram shape; and wherein two selvage edges are disposed along adjacent sides of the parallelogram.

12. The photovoltaic element of claim 1, wherein the one or more selvage edges have an adhesive material disposed on their top surfaces.

13. The photovoltaic element of claim 1, wherein the selvage edge has a relatively rigid material disposed thereon.

14. The photovoltaic element of claim 1, wherein the photovoltaic element further comprises a raised feature on its top surface adjacent the selvage edge.

15. The photovoltaic element of claim 1, wherein the photovoltaic element is formed as a laminate or encapsulate structure, and wherein the selvage edge is formed from a layer of laminate or encapsulant material.

16. A photovoltaic system comprising a plurality of photovoltaic elements according to claim 1, arrayed on a surface, wherein one or more of the selvage edges are covered by an edge of an adjacent photovoltaic element.

17. The photovoltaic system according to claim 14, wherein the one or more of the selvage edges are adhered to the bottom surface of the edge of the adjacent photovoltaic element.

18. A roof comprising a roof deck and a photovoltaic system according to claim 15 disposed on the roof deck.

19. A method for installing a photovoltaic system, the method comprising disposing a plurality of photovoltaic elements according claim 1 on a surface.

20. A kit for the installation of a photovoltaic system, the kit comprising a plurality of photovoltaic elements according to claim 1.
